(19) United States
(12) Patent Application Publication
(10) Pub. No.: US 2003/0037813 A1
(43) Pub. Date: Feb. 27, 2003

(54) System for converting sunlight to artificial light

(76) Inventor: Frans Louis Jansen, Oss (NL)

Correspondence Address: Michael E. Marion, U.S. Philips Corporation, 580 White Plains Road, Tarrytown, NY, 10591, US

(21) Appl. No.: 10/225,797

(22) Filed: Aug. 22, 2002

(30) Foreign Application Priority Data
Aug. 27, 2001 (EP) 01203232.2

(51) Int. Cl. H01L 31/00

(52) U.S. Cl. 136/244; 136/293

(57) ABSTRACT

In a system for converting sunlight to artificial light, the solar energy is converted to as much DC power as the light sources require (each light source including a ballast circuit and a lamp). If the solar power lags behind the power consumed by the light sources, additional power is supplied to the light sources from the mains. If the solar power exceeds the power consumed by the light sources, the excess solar power is converted to mains power.

The invention relates to a system for converting sunlight to artificial light, which system comprises connections for solar panels and/or photovoltaic generators, as well as connections to an electric power mains and connections for illumination units.

The use of solar panels or photovoltaic generators to generate energy in the form of DC voltage energy from sunlight and store this energy temporarily in accumulators so as to use this energy at a later stage when sunlight is absent to feed illumination units is well-known. It is also well known to deliver the energy generated from sunlight via a suitable converter to an electric power mains and, at a later stage, when sunlight is absent, draw energy from the same electric power mains in order to feed illumination units. See, for example, DE 19723617 A1.

It is an object of the invention to provide a system of the type mentioned above, the integrated arrangement of the energy sources and energy loads/illumination units of which enables a modular structure of a widespread illumination system allowing energy to be saved and energy to be recovered for, for example, buildings with a large surface to be illuminated and a large roof surface exposed to sunlight.

This object in accordance with the invention is achieved by a system for converting sunlight to artificial light, which system comprises connections for solar panels/photovoltaic generators, an electric power mains and illumination units, characterized in that, after suitable conversion of the electric energy generated by the solar panels/photovoltaic generators, said energy is delivered directly to the illumination units and, dependent upon the demand for artificial light and/or the presence of sunlight, any surplus of electric energy produced from sunlight is delivered to the electric power mains or the deficiency in energy produced from sunlight is drawn from the electric power mains.

In accordance with a further development according to the invention, the system comprises a central DC voltage bus, wherein DC/DC conversion circuits are arranged between said connections for the solar panels/photovoltaic generators and the central DC voltage bus, a bidirectional AC/DC conversion circuit is arranged between said connection for the electric power mains and the DC voltage bus, and the illumination units each comprise a DC voltage input that is connected directly to the DC voltage bus.

The illumination units preferably are fluorescent lamps (low-pressure discharge lamps) with ballasts that, in the case of the invention, do not require a separate AC/DC conversion circuit.

The voltage applied to the DC voltage bus may be as high as 200 V or 400 V, which are customary values in currently used ballasts for, inter alia, HID lamps (HID means “High Intensity Discharge”), or as low as 42 V, which is more suitable for a possible energy storage in emergency batteries and allows said batteries to be touched more safely.

These and other aspects of the invention are apparent from and will be elucidated with reference to the embodiment(s) described hereinafter.

In the drawings:

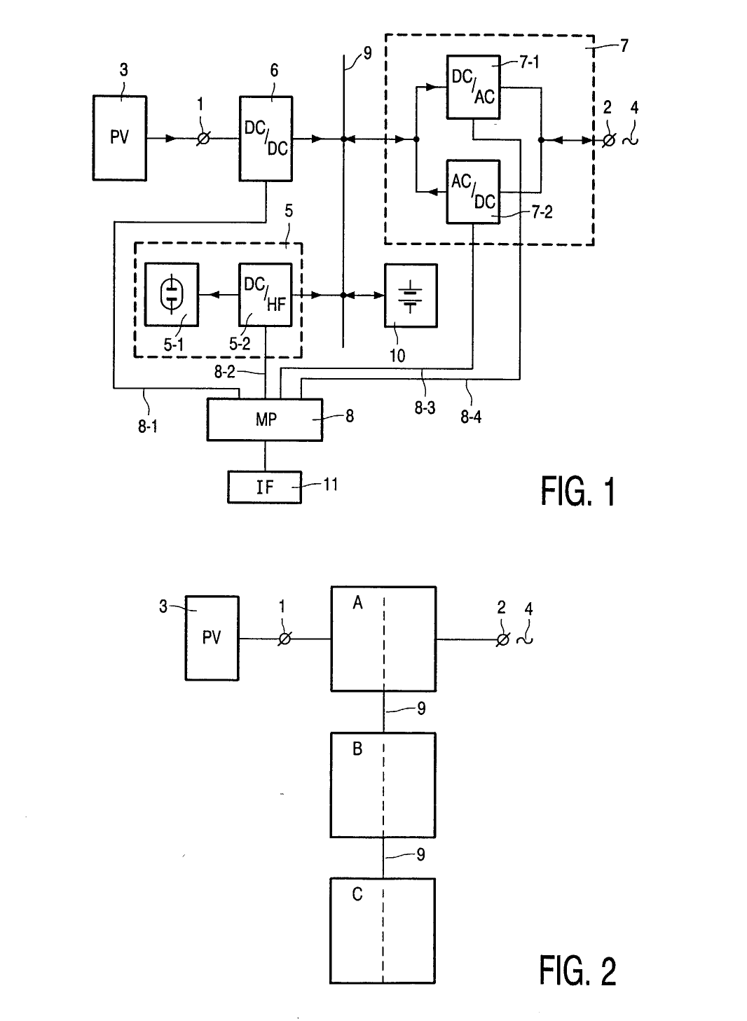

FIG. 1 shows a block diagram of a system in accordance with the invention, and

FIG. 2 shows a block diagram of a modular system in accordance with the invention.

The illumination system shown in FIG. 1 comprises connections 1 and 2 for, respectively, solar panels/photovoltaic generators PV(3) and an electric power mains 4.

The system further comprises an illumination unit 5 that is representative of a possibly larger number of illumination units, a DC/DC conversion circuit 6, a bidirectional AC/DC conversion circuit 7 and a microcontrol unit 8.

The illumination unit 5 includes a lamp 5-1, in general a discharge lamp, and a DC/high-frequency conversion circuit 5-2 in the case of a fluorescent lamp. In the case of a HID lamp, the circuit 5-2 could be a high-frequency generator or a low-frequency square-wave generator.

If the PV generator receives sufficient sunlight to supply a usable amount of electric power, the conversion circuit 6 converts the output DC voltage from the PV generator 3 to a value that is standardized for the system of for example 200 volts on a DC voltage bus 9. This voltage is directly delivered to a DC voltage input of the illumination unit 5 in order to be converted by the conversion circuit 5-2 to a voltage for operating the lamp 5-1.

In the manner described above, sunlight is converted to artificial lamplight if sufficient sunlight is available and, at the same time, there is a demand for artificial light.

The bidirectional conversion circuit 7 is arranged between the DC voltage bus 9 and the connection 2 of the electric power mains 4, which bidirectional conversion circuit draws energy from the electric power mains 4 if there is little or no sunlight, and can make this energy available in the form of DC voltage power on the bus 9.

If the DC voltage power made available on the bus 9 by the PV generator 3 via circuit 6 exceeds the power consumed by the illumination unit 5, the conversion circuit 7, operating in the opposite direction, can deliver the excess power in the form of AC voltage power to the electric power mains.

FIG. 1 shows that the conversion circuit 7 consists of the parallel arrangement of a DC/AC conversion circuit 7-1 and an AC/DC conversion circuit 7-2, which can be controlled so as to be alternately operative. In practice, a unitary circuit is possible that, dependent upon the control, operates in either of the two directions.

As shown in FIG. 1, the illumination unit 5 does not require an AC/DC conversion circuit that is normally necessary for a direct connection to the electric power mains. Of course, this is even more advantageous if more than one illumination unit is connected to the bus 9.

The system shown in FIG. 1 further comprises a microcontrol unit 8 that is connected to the different system units by means of the (bidirectional) control lines 8-1 through 8-4. Via these lines status signals can be received from the units and control signals can be supplied to the unit. The above description regarding possible applications of the illumination system should enable people skilled in the art to suitably program the microcontrol unit.

Programming is to be taken to mean herein, inter alia, determining whether the power supplied by the PV generator 3 is higher than the power consumed by the illumination unit 5, in which case the conversion circuit 7-1 will be activated so as to deliver the excess energy to the electric power mains 4. In the opposite case, the microcontrol unit will be programmed such that the conversion circuit 7-2 becomes operative to withdraw energy from the electric power mains 4 and deliver this energy, in the form of DC voltage energy on the bus 9, to the illumination unit 5.

In emergency cases, for example in case of failure of the electric power mains 4, a battery unit 10 can be provided that is connected to the bus and that is possibly equipped with a DC/DC conversion circuit for increasing the battery voltage to the standardized voltage for the bus 9. The battery can be charged from the electric power mains 4, or from the bus 9 via the voltage conversion circuit that may be present in the battery 10, if excessive power is available on the bus, which charging operation will be controlled by means of the control unit 8.

The interface 11 connected to the control unit 8 will enable, for example, the illumination units to be remote-controlled and dimmed by transferring the relevant signals to the control unit 8.

It will be obvious that the system shown in FIG. 1 may comprise more than one PV generator 3 and more than one illumination unit, and that each illumination unit may comprise more than one lamp.

FIG. 2 shows the possibility of a hierarchical system comprising a number of modules A, B and C, each in accordance with FIG. 1 yet, possibly, without the connection 1 and/or 2, which modules are arranged so as to be spatially distributed and comprise a common DC voltage bus 9. For larger distances between the modules it would be possible to choose a lower voltage of, for example, 42 V as the voltage of the bus 9.

It is further noted that also other applications can be connected to the DC voltage bus 9, such as audio and video equipment, computer equipment and, in general, various types of electronic equipment as well as fans, water pumps etc., for example for agrarian applications.

In summary, the invention has the following advantages:

The proposed system is more suitable than systems in accordance with the prior art (fewer or simpler conversion steps; more efficient, more economical).

The proposed system enables the number of AC/DC converters connected to the electric power mains to be reduced, in particular the number of converters for electronic apparatus;

The invention makes it possible to connect other applications to the central DC voltage bus of the system;

The voltage on the DC voltage bus can be chosen so as to be optimal. For HID lamps a voltage of 200 V could be suitable, which will lead to a reduction of the costs of the converter for the solar panel and the converter of the lamp conversion circuit.

1. A system for converting sunlight to artificial light, which system comprises connections for solar panels and/or photovoltaic generators, as well as connections to an electric power mains and connections for illumination units, characterized in that, after suitable conversion of the electric energy generated by the solar panels and/or photovoltaic generators, said energy is delivered directly to the illumination units and, dependent upon the demand for artificial light and/or the presence of sunlight, any surplus of electric energy produced from sunlight is delivered to the electric power mains or the deficiency in energy produced from sunlight is drawn from the electric power mains.

2. A system as claimed in claim 1, characterized in that the system comprises a central DC voltage bus, wherein DC/DC conversion circuits are arranged between said connection for the solar panels and/or the photovoltaic generators and the central DC voltage bus, a bidirectional AC/DC conversion circuit is arranged between said connection for the electric power mains and the DC voltage bus, and the illumination units each comprise a DC voltage input that is connected directly to the DC voltage bus.

3. A system as claimed in claim 2, characterized in that a number of modules with illumination units having DC voltage inputs are connected to a module and/or a DC voltage bus.

4. A system as claimed in claim 2 or 3, characterized in that an auxiliary device, such as an auxiliary battery, is connected to the central DC voltage bus.

5. A system as claimed in claim 2, 3 or 4, characterized in that other sinks, such as fans, pumps, computers, audio-video equipment, are connected to the central DC voltage bus.
